(19) United States
(12) Patent Application Publication
(10) Pub. No.: US 2026/0075737 A1
(43) Pub. Date: Mar. 12, 2026

(54) M.2 EDGE CONNECTOR MODULE

(71) Applicant: HEWLETT PACKARD ENTERPRISE DEVELOPMENT LP, Spring, TX (US)

(72) Inventors: Chih-Wei Chiang, Taoyuan City (TW); Chui Ching Chiu, Taoyuan City (TW); Peng Chianghsieh, Taoyuan City (TW)

(21) Appl. No.: 18/882,937

(22) Filed: Sep. 12, 2024

(51) Int. Cl. H05K 7/14; H01R 12/70; H01R 12/72; H01R 43/26

(52) U.S. Cl. CPC H05K 7/1452; H01R 12/7005; H01R 12/722; H01R 43/26

(57) ABSTRACT

A device, system and method, the device including a printed circuit board (PCB) configured to mate with an M.2 assembly of a primary board, the M.2 assembly comprising a plurality of M.2 sockets and at least one holder and one or more components mounted to the PCB, wherein the PCB comprises: a first end configured to mate with at least two M.2 sockets of the plurality of M.2 sockets of the M.2 assembly and a second end comprising at least one attachment feature and configured to removably engage with the at least one holder.

### INTRODUCTION

Some information processing devices are configured to allow for removable modules, such as Open Compute Project (OCP) network interface card (NIC) modules or Datacenter Secure Control Modules (DC-SCM), to be installed therein. To facilitate this, the device may include bays to receive the modules and the primary system board of the device may include electrical connectors complementary to the modules to electrically connect the modules with the primary system board. Usually, for OCP modules, the connectors are straddle-mounted to the rear edge of the primary system board such that the OCP modules, when installed, sit between the rear edge of the primary system board and the rear panel of the chassis.

### BRIEF DESCRIPTION OF THE DRAWINGS

The present disclosure can be understood from the following detailed description, either alone or together with the accompanying drawings. The drawings are included to provide a further understanding of the present disclosure and are incorporated in and constitute a part of this specification. The drawings illustrate one or more examples of the present teachings and together with the description explain certain principles and operations. In the drawings:

FIG. 1 is a block diagram illustrating an example of a device that includes a printed circuit assembly, the printed circuit assembly including M.2 connectors, attachment features and a printed circuit board with components installed.

FIG. 2 is a block diagram illustrating an example system that includes a chassis, a primary system board, communicatively connected to the device of FIG. 1, including a M.2 module, which includes a M.2 bay, M.2 sockets and holders.

FIG. 3 is an exploded view of an example system, which includes a printed circuit assembly with M.2 connectors and attachment features, and a M.2 assembly with M.2 sockets, holders and an M.2 bay.

FIG. 4 is a perspective view of the example M.2 assembly of FIG. 3.

FIG. 5 is a perspective view of the M.2 assembly of FIGS. 3 and 4 with M.2 solid state drives installed.

FIG. 6 is a perspective view of the system of FIG. 3 shown in a partially installed state of the printed circuit assembly in the M.2 assembly.

FIG. 7 is a perspective view of the system of FIG. 3 shown in an installed state of the printed circuit assembly in the M.2 assembly.

FIG. 8 is a perspective view of an example holder of an M.2 assembly.

The drawings are included to provide a further understanding of the present disclosure and are incorporated in and constitute a part of this specification. The drawings illustrate one or more examples of the present teachings and together with the description explain certain principles and operations. In some occasions, details that are not necessary for an understanding of an instance of this disclosure or that render other details difficult to perceive may have been omitted.

### DETAILED DESCRIPTION

Some information processing systems might lack the capability to receive certain removable modules, such as OCP modules. For example, the information processing system may lack a compatible electrical connector on its primary system board which can connect with the module. As another example, the information processing system may lack a bay in which the module can be received and supported.

In some cases, it may be possible for a manufacturer of the information processing system which previously lacked capability to receive a module to redesign the system to add this capability, for example by adding a connector to the system board and/or a bay in the chassis. But redesigning the system in this manner may require developing a new system board, a new chassis, and/or a new component layout within the chassis, each of which can be costly and challenging.

Moreover, a manufacturer who redesigns a system to add capability to receive a module may also desire to continue offering the original version of the system, which lacks the capability to receive the module, alongside the new version of the system. This may be desired in some cases because some customers may desire the new version (e.g., because it can receive the modules) while some other customers may prefer the original version (e.g., because they don't want to use the modules and because the original version might cost less than the new version or might have some other capability they want). But producing multiple different versions of the system, which may have different components (e.g., different primary system boards) with different stock-keeping unit (SKU) or parts numbers, can increase development, manufacturing, and logistical costs.

In addition, in some cases, it might not be feasible to add a bay in the chassis to receive the module and/or to add a compatible connector to the primary system board in a position where it is usable to receive the module. Adding the connector and/or bay may be infeasible in some cases due to space, cost, capability, or other constraints.

For example, information processing systems designed for use in some specialized environments, such as Telco and Edge computing environments, often are smaller in size than datacenter information processing systems, and thus space is at a premium inside their chassis and on their primary system boards. Because the system boards are small, they are usually densely packed with components, meaning that there may simply be no room on the system board for adding an OCP connector, at least not without omission of some other component. Furthermore, even if an OCP connector could be added somewhere on the board, there may not be sufficient free space around that connector in which an OCP bay could be added to receive an OCP module—for example, OCP modules are usually disposed between the rear edge of the primary system board and the rear panel, but in many Telco and Edge there is little to no free space in this region. Thus, in many cases it is infeasible to add OCP connectors and bays to information processing systems designed for use in these specialized environments, such as Telco and Edge computing environments.

To address the above-mentioned challenges, the disclosure provides a module that is configured to operate as an OCP module (such as a DC-SCM or OCP NIC 3.0 module) but which may deviate from the OCP specifications in that the module lacks the OCP-specified connector (e.g., a 4C+ edge connector) and instead comprises a new connector which includes multiple M.2 edge connectors arranged in group. This module may be referred to herein as an M.2 OCP module. The M.2 edge connectors of the M.2 OCP module are configured to mate with corresponding M.2 sockets mounted to a primary system board, thereby electrically connecting the M.2 OCP module to the primary system board.

Because the M.2 OCP module is electrically connected to the primary system board via M.2 sockets, the system does not need an available OCP connector in order to receive the module. In other words, OCP functionality can be added to the system (via installation of the M.2 OCP module) even if the system lacks OCP connectors. Furthermore, many primary system boards already have existing M.2 connectors disposed thereon, and thus in many cases these system boards can have OCP functionality added thereto, via the M.2 OCP module, without the manufacture having to redesign the system board to add connectors.

In some examples, an M.2 drive bay may be disposed adjacent to the M.2 connectors, with the M.2 drive bay including a reserved space in which M.2 drives can be disposed, as well as some support features to secure and support the drives. In some examples, the M.2 OCP module may be disposed within this M.2 drive bay, either in addition to or in lieu of the M.2 drives. In other words, the M.2 OCP module does not require a separate OCP bay to be received within. Furthermore, many systems already have existing M.2 drive bays, and thus in many cases these system boards can have OCP functionality added thereto, via the M.2 OCP module, without the manufacture having to redesign the chassis or system board to accommodate a new OCP bay.

Thus, the M.2 OCP module can be used to add OCP functionality to systems without OCP connectors or OCP bays, where it might have previously been difficult, or even impossible, to add OCP functionality. Moreover, in many cases a manufacturer of the system can add the OCP functionality via the M.2 OCP module without having to redesign the primary system board or the chassis to add OCP connectors or OCP bays. This can also allow the manufacturer to provide different versions of the system, such as one that has OCP functionality and one that does not, while still maintaining the same system board design and the same chassis design between the different systems, thereby reducing development, manufacturing, and logistical costs.

In some examples, the M.2 sockets may be arranged in the system board in a stacked configuration, wherein the double stacked configuration allows the M.2 OCP module to be connected to the M.2 sockets at the top of the stack while still allowing M.2 drives to be connected to the M.2 sockets at the bottom of the stack. By using the stacked configuration with M.2 drives at the bottom of the stack and M.2 OCP module at the top of the stack, a system that otherwise would either have the M.2 drives or the M.2 OCP modules can have both installed.

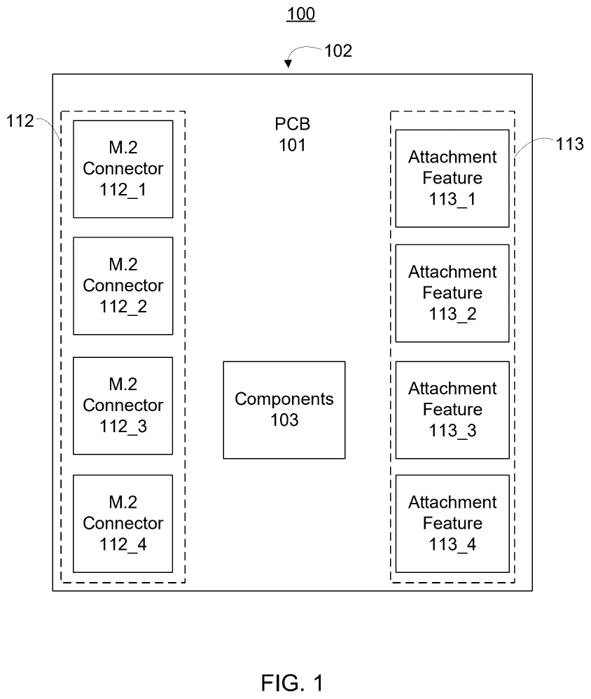

These and other examples will be described in greater detail below in relation to FIGS. 1-8.

Now referring to FIG. 1, a device 100 with M.2 edge connectors is shown. Device 100 is a removable module configured to be removably installed in an information processing system, such as a server, networking device, or other information processing system. In particular, the device 100 is configured to mimic an OCP module, such as a DC-SCM or NIC 3.0 module, and thus the device 100 has components configured to provide the functionalities of the OCP module and also has the same physical form factor as the OCP module, as specified in the relevant OCP standards/specifications, with a few exceptions noted below. Specifically, the device 100 uses multiple M.2 edge connectors instead of an OCP edge connector (e.g., 4C or 4C+ connector), as will be described in greater detail below. Thus, the device 100 is an example of the M.2 OCP modules described above.

Device 100 comprises a PCA 102 which includes a PCB 101 and one or more information processing components 103 mounted to the PCB 101. PCB 101 includes multiple M.2 edge connectors 112 and attachment features 113. The M.2 edge connectors 112 are formed in one edge of the PCB 101, and are configured to mate with corresponding M.2 sockets mounted to some another board of the information processing system, such as the main system board. The attachment features 113 are configured to engage with a physical support structure of the information processing system to support and/or secure the device 100 in the system. These components will be described in greater detail in turn below.

In FIG. 1, four of the M.2 edge connectors 112 are illustrated to facilitate discussion, namely M.2 edge connectors 112_1, 112_2, 112_3 and 112_4, but the PCB 101 may comprise any number equal to or greater than two (2) of the M.2 edge connectors 112. It should be noted that in some examples, the PCB 101 may include fewer M.2 edge connector 112. In still other implementations, the PCB 101 may include more M.2 edge connectors 112 than shown in FIG. 1. In some examples, the number of M.2 edge connectors 112 that are included in an implementation of the device 100 may depend on the number and type of signals that are needed to provide the desired OCP functionality. In some cases, four M.2 edge connectors 112 may be sufficient to carry the signals needed to provide the same functionality as one OCP 4C or 4C+ connector. Accordingly, in some implementations in which the device 100 is configured to mimic an OCP module which would normally have one OCP 4C or 4C+ connector (e.g., a DC-SCM or a NIC 3.0 module), the device 100 may have four M.2 edge connectors 112, while in some other implementations in which the device 100 is configured to mimic an OCP module which has two OCP 4C+ or 4C connectors (e.g., a large-form-factor (LFF) OCP module), the device 100 may have eight M.2 edge connectors 112.

As mentioned above, device 100 is configured to operate as an OCP module. As such, although the M.2 edge connectors 112are referred to as “M.2 edge connectors,” it should be noted that they are “M.2 edge connectors” in the sense that they have substantially the same physical form factor as a standard M.2 edge connector, but they do not necessarily carry the same types of electrical signals as a standard M.2 edge connector. The M.2 edge connectors 112 having substantially the same form factor as a standard M.2 edge connector means that the size and shape of each M.2 edge connector 112, including any keying features thereof, comply with or are compatible with an M.2 standard/specification for an edge connector, such that each M.2 edge connector 112 is capable of matting with a standard M.2 socket (a standard M.2 socket being a socket which complies with an M.2 standard and can receive a standard M.2 edge connector). Furthermore, this also means that the layout and structure of the pins (electrical contacts) of the M.2 edge connectors 112 are compatible with an M.2 standard, meaning that the pins are arranged to be capable of engaging respectively corresponding pins in a standard M.2 socket. Although the M.2 edge connectors 112 have substantially the same physical form factor as a standard M.2 edge connectors, in some examples, they do not necessarily have a standard M.2 pinout, wherein in this context “pinout” refers to the assignment of certain electrical signals to certain pins. Instead, because the use case is not the same as most M.2 devices, the pinout may differ between standard M.2 connectors and the M.2 edge connectors 112 described herein.

As an example, the pinout of the M.2 edge connectors 112 would include assignments of certain OCP module signals utilized by an OCP module, such as DC-SCM or OCP NIC 3.0 modules, to certain pins of the M.2 edge connectors. For example, a Small Form Factor (SFF) OCP NIC. 3.0 module utilizes the signals specified in Table 18, page 84, of the OCP NIC 3.0 standard, and thus in an implementation of the device 100 configured to mimic an SFF OCP NIC 3.0 module, these same OCP module signals may be assigned to pins of the M.2 edge connectors 112. In instances, depending on the use case, all four M.2 edge connectors 112 may need to be used in order to transmit signals because the pins would be insufficient if less M.2 edge connectors 112 are used. For example, device 100 operating as a DC-SCM module may need to use the pins from four M.2 edge connectors 112, while, as an example, a device 100 operating as a an OCP module which would ordinarily have a NIC 3.0 2C connector may need fewer pins, thus the device 100 would require fewer than the four M.2 edge connectors 112 shown.

PCB 101 also includes one or more attachment features 113. Although in FIG. 1 four attachment features 113 are shown, namely attachment features 113_1, 113_2, 113_3 and 113_4, it should be noted that in various examples more or fewer than four may be included. In some examples, the attachment features 113 are disposed on, in, or adjacent to an edge of the PCB 101 which is opposite from the edge which has the M.2 edge connectors 112. In some examples, the attachment features 113 are formed as an integral part of the PCB 101, such as one or more screw holes through the PCB 101, one or more notches in an edge of the PCB 101, or the whole edge of the PCB 101 opposed to the M.2 connectors 112 may itself be one attachment feature 113 (e.g., the edge may mate with a clamp-like mechanism for holding the device 100 in the installed position). In other examples, the attachment features 113 are formed by parts which are initially separate from the PCB 101 and are later coupled thereto, such as a latch a bar or other mechanism that is attached to the PCB 101 and configured to mate with a holder. In other words, any number and type of attachment features 113 may be used, as long as a secure attachment can be achieved by the configuration (i.e. number and type of attachment feature 113) used.

In some examples, the attachment features 113 comprise M.2 attachment features, wherein an M.2 attachment feature comprises a semi-circular notch or cutout formed in an edge of the PCB 101, which is configured to mate with an M.2 holder of the information processing system (the M.2 holder being a support structure which is configured to engage with and support/secure an M.2 module). The notch may have a shape and dimensions as specified by an M.2 standard/specification.

As noted above, the PCA 102 comprises the PCB 101 and also one or more components 103 mounted to the PCB 101. As used herein, the PCA 102 is the device which is formed by the PCB 101 in a state with the one or more components 103 communicatively attached thereto. Although the device 100 is described herein in a state in which the components 103 are attached to the PCB 101 to form PCA 102, it should be understood that in some examples the device 100 may comprise the PCB 101 alone without the components 103 having yet been attached thereto.

Components 103 may include one or more electrical (or electro-optical) components, which may include information processing components such as a microprocessor, Application Specific Integrated Circuity (ASIC), Field Programable Gate Array (FPGA), Complex Programmable Logic Device (CPLD), or other information processing component. In some examples, the components 103 of the PCA 102 may include the same or similar components as would be found in the OCP module which the device 100 is mimicking. For example, if device 100 is configured to operate as an OCP NIC 3.0 module, then PCA 102, in this example case, would include most or all electrical (or electro-optical) components that are included in an OCP NIC 3.0 module, with the exclusion of the OCP connectors of the OCP module (and associated circuitry) which is replaced in the device 100 with the M.2 connectors 112. It should be noted that components 103, as described throughout this disclosure, do not include electrical connectors or attachment features. As such, where PCA 102 is described as including all components of a use case form factor (e.g. DC-SCM form factor), it should not be interpreted as including the attachment features or connectors of that form factor.

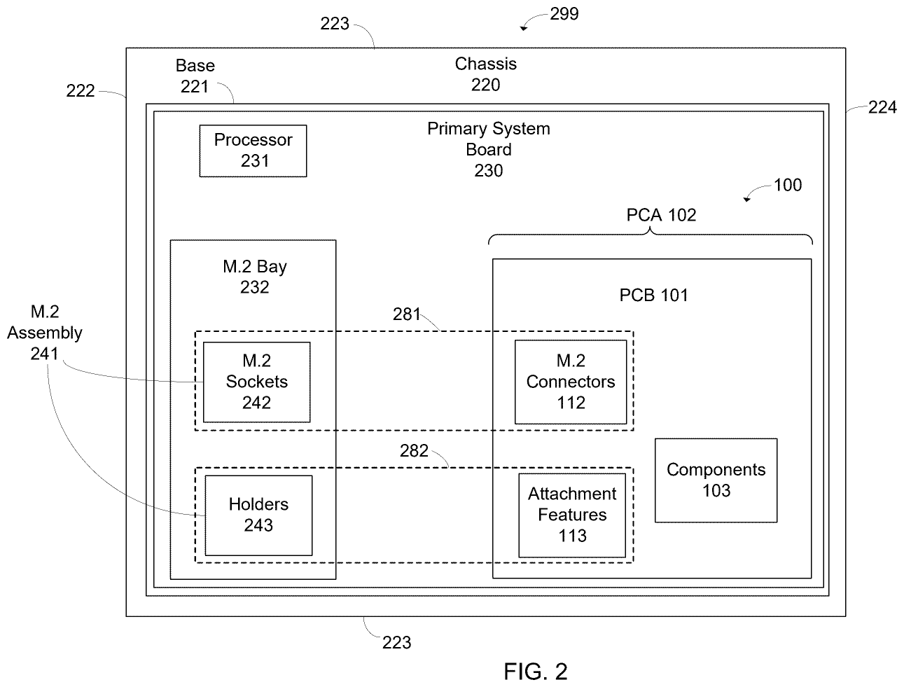

Referring to FIG. 2, an example system 200 is shown. System 200 is an information processing system, such as a server, networking device, or other information processing system. System 200 includes a chassis 220, a primary system board 230 supported by the chassis 220, an M.2 bay, and a device 100 removably installable in the M.2 bay.

A “chassis,” as used herein, is a support structure, such as an enclosure or tray, designed to support, and in some cases house, hardware components. Chassis 220 includes at least a base 221. A “base” as used herein is a component, or section, of chassis 220 that extends parallel to and provides structural support for a system board, such as a motherboard. In some instances, chassis 220 may also include additional support structures beyond the base 221. For example, in some implementations chassis 220 takes the form of a box-like housing or enclosure, which has as a rear panel 220, two side walls 223, and a front panel 224 coupled perpendicularly to the base 221, as well as a cover (not illustrated) disposed opposite from the base 221 and coupled perpendicularly to the rear panel 220, side walls 223, and/or front panel 224 (in some cases, the cover may be openable or removable).

As noted above, system 200 includes a primary system board 230. In instances, chassis 220 may house primary system board 230. In instances, primary system board 230 may be attached to base 221. Primary system board 230 includes a processor 231. As used herein, a “processor” is a component configured for executing instructions, performing calculations and managing tasks.

System 200 also includes an M.2 bay 232. As used herein, a “bay” is a receptacle within a system which is configured to receive a removable module. This receptacle includes both a designated region (volume) of space in which the module can be disposed and also includes attachment features and electrical connectors arranged in that region to secure and electrically connect the removable module to a host board, such as the primary system board 230. In the specific case of the M.2 bay 232, the bay 232 comprises M.2 sockets 242 and M.2 holders 243 mounted to the primary system board 230 as well as the volume of space positioned directly above the primary system board 230 between the M.2 sockets 242 and M.2 holders 243. The M.2 sockets 242 and holders 243 will be described in greater detail below. The M.2 bay 232 is configured to interchangeably receive either one or more M.2 modules (e.g., M.2 solid state drives (SSD)), one or more instances of the device 100, or a combination of M.2 modules and the device 100.

In an installed state of the device 100 in the M.2 bay 232, the M.2 edge connectors 112 of the device 100 mate with the M.2 sockets 242, and thus the primary system board 230 is communicatively connected to device 100 via the M.2 edge connectors 112 and M.2 sockets 242. Furthermore, the attachment features 113 of the device 100 engage with the holders 243 to secure the device 100 to the system board 230. Device 100 includes all components discussed in reference to FIG. 1.

System 200 includes a M.2 assembly 241. M.2 assembly 241, as used herein, is the combination of M.2 sockets 242 and holders 243 attached to the system board 230 to form the M.2 bay 232. M.2 assembly 241 includes two or more M.2 sockets 242 and one or more holders 243. The number of M.2 sockets 242 may be equal to or greater than the number of M.2 edge connectors 112 to ensure that each M.2 edge connector 112 can mate with a corresponding M.2 socket 242. It should be noted that in some situations, the number of M.2 edge connectors 112 and the number of attachment features 113 matches the number of M.2 sockets 242 and the number of holders 243, respectively. For example, in some implementations of the system 200 there are four M.2 sockets 242 and four holders 243 which may receive a device 100 that includes four M.2 edge connectors 112 and four attachment features 113. However, the number of M.2 edge connector 112 does not necessarily need to match the number of M.2 sockets 242. For example, if device 100 only includes three M.2 edge connectors 112 while M.2 assembly 241 has four M.2 sockets 242, three of those sockets would be used while the fourth one would stay unused by device 100. Similarly, the number of holders 243 does not necessarily need to match the number of attachment features 113.

As mentioned above, each M.2 edge connector 112 shares the form factor of a connector used for M.2 connections. However, the pins would be configured to carry the signals used by device 100, which would depend on the use case. For example, the pin configuration of the M.2 edge connectors 112 for a device 100 configured to operate as a DC-SCM module would likely differ from the configuration used for a NIC 3.0 use case.

In instances, M.2 edge connectors 112 may be configured to mate with a M.2 M-key type of socket. In some instances, M.2 connector 112 may be configured to mate with a M.2 B-key type. In instances, M.2 connector 112 may be configured to mate a M.2 B+M-key type. For example, M.2 connectors 112 may mate with all three types of M.2 key configurations, thus making the device 100 capable of being installed in multiple key typed M.2 sockets 242. As it would be understood by one of ordinary skill in the art, “M” and “B” keys refers to the keying, or notch, types of the sockets as defined by M.2 specifications. For example, a B-key may have a notch located close to M.2 pins 12-19, while the M-key may have a notch located close to 59-66. It would also be understood that the B+M-key type is configured to receive B-keyed and M-keyed modules.

In the example system 200, the dashed rectangle 281 shows the connection between the M.2 edge connectors 112 of the device 100 and the M.2 sockets 242 when device 100 is in an installed state. The dashed rectangle 282 shows the attachment between the attachment features 113 and the holders 243 when device 100 is in an installed position. An installed state of the device 100 as used herein is when device 100 is inserted into the bay 232 and communicatively connected to the M.2 assembly 241. In cases in which the M.2 assembly 241 includes holders 243, the installed state may include the M.2 edge connectors 112 being mated with the M.2 sockets 242 and the attachment features 113 being engaged with the holders 243. It should be noted that although holders 243 and attachment features 113 are described in the examples herein, other forms of attachment could be included in other examples. As such, device 100 may be considered to be in an installed state even if the attachment features 113 are not used in the manner described in this disclosure. In examples in which holders 243 are omitted, the installed state may refer simply to the edge connectors 112 being engaged with M.2 sockets 242. For example, the connection 281 between the M.2 connectors 112 and the M.2 sockets 242 could provide the attachment, thus device 100 would be in an installed state even if the attachment features 113 were not used. As such, an installed state is defined by the connection 281 between M.2 edge connectors 112 and M.2 sockets 242.

In some examples, M.2 assembly 241 may include components spacers placed between the M.2 sockets 242 and the system board 230 and/or between the holders 243 and the system board 230. As used herein, a component spacer is a component used for providing physical separation between primary system board 230and an M.2 socket 242 or a holder 243, and also for providing structural support for the M.2 socket242 or the holder 243. For example, in a system 200 where chassis 220 provides enough space for the spacers to be used, M.2 sockets 242/holders 243 may be elevated in relation to primary system board 230. In other examples, the M.2 sockets 242 and holders 243 may be configured to have a tall form factor which elevates the mating/engagement points thereof without needing to dispose a spacer between the system board 230 and the M.2 sockets 242/holders 243. Elevating the mating/engagement points of the M.2 sockets 242 and holders 243, whether through the use of a spacer or through using taller sockets 242/holders 243, may provide more space between the system board 230 and the modules mated with the M.2 sockets 242, which may allow for the installation of components on the system board 230 in the region below the modules. In contrast, without elevating the M.2 sockets 242 and holders 243, when modules are installed the modules may be positioned close to the surface of the primary system board 230 and thus components may need to be omitted from the system board 230 in that region to avoid interference between the components and the modules installed in the M.2 sockets 242.

It should be noted that FIGS. 1 and 2 are meant to convey a conceptual representation of device 100 and system 200. As such, these block diagrams should not be interpreted as conveying any specific structure or physical or spatial relationships between components and are not limited to any structures described herein.

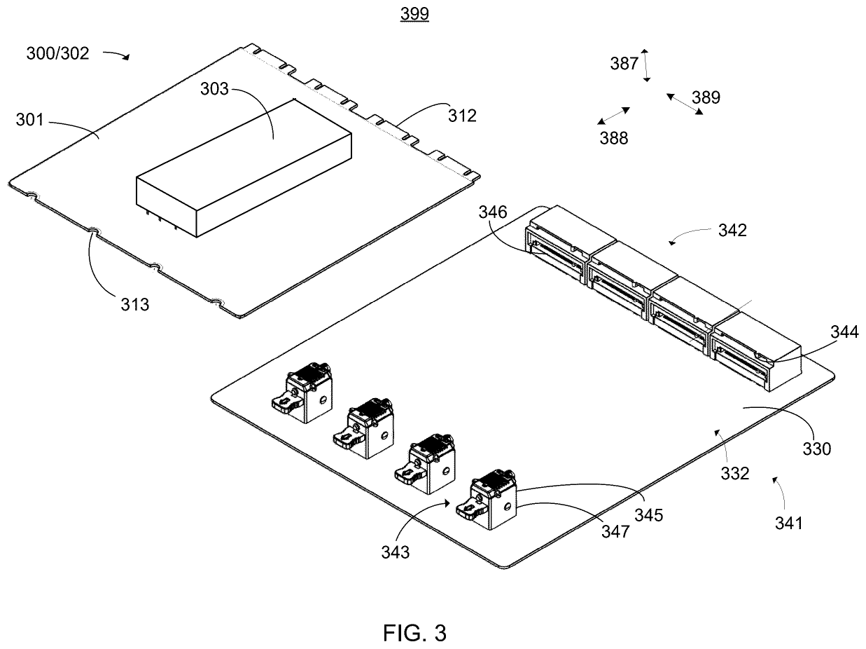

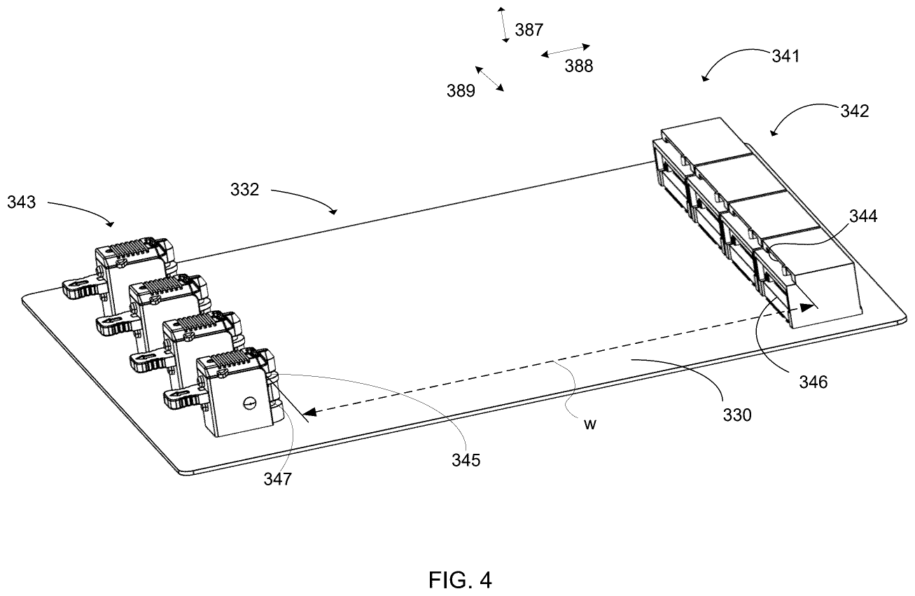

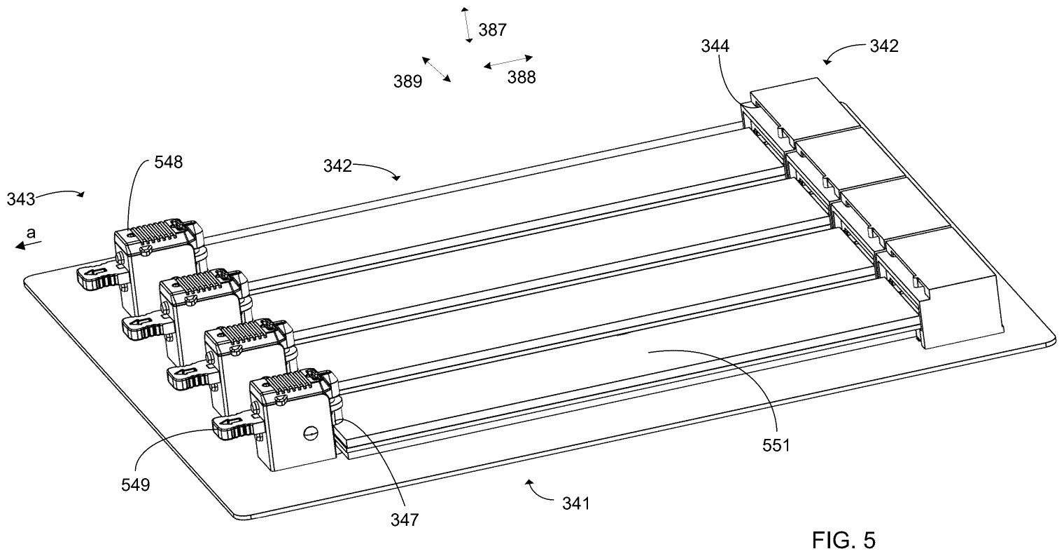

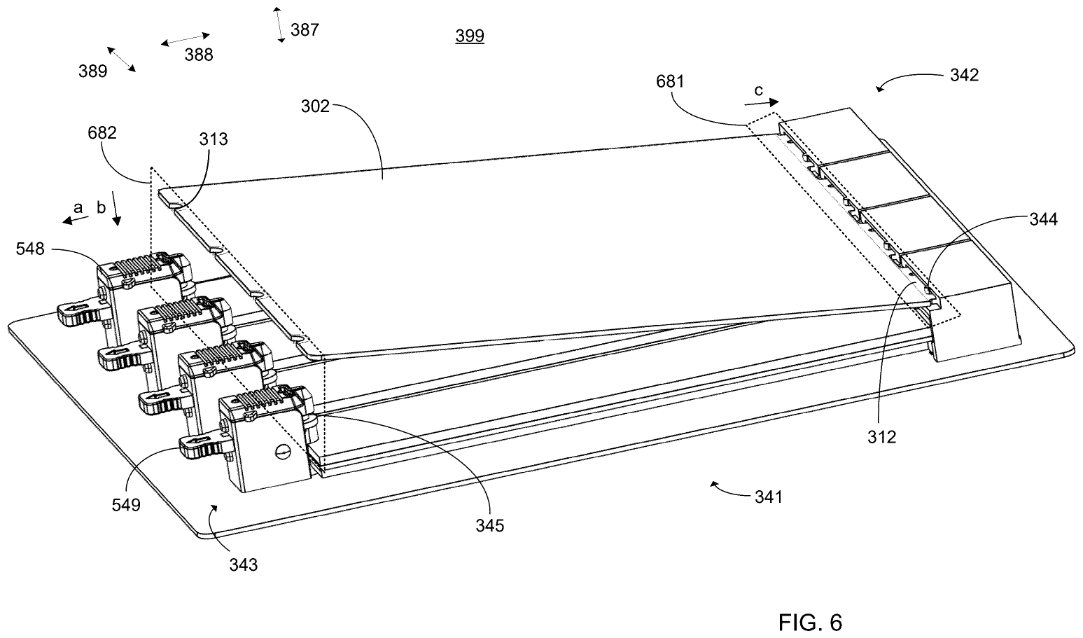

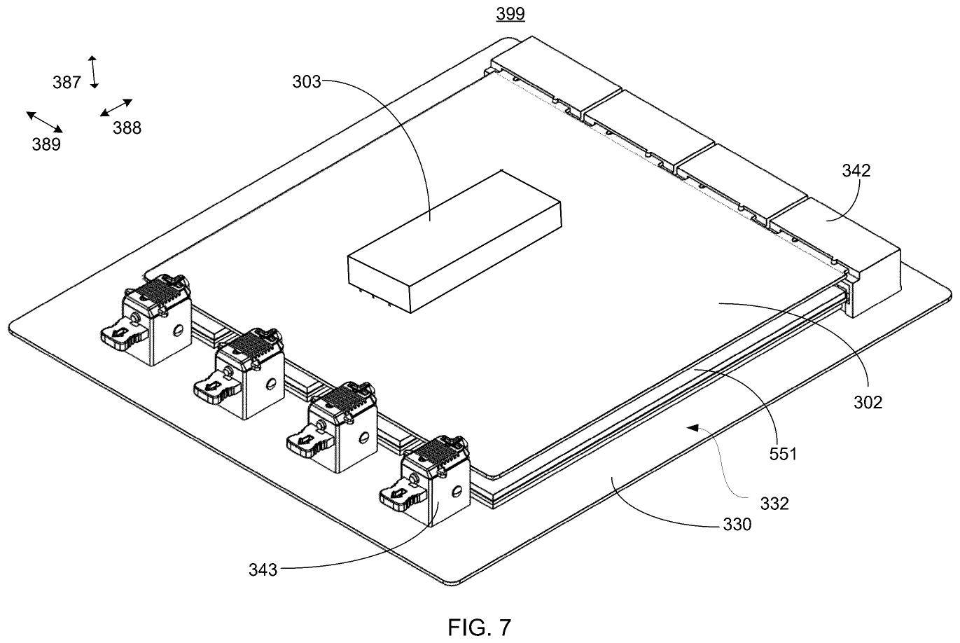

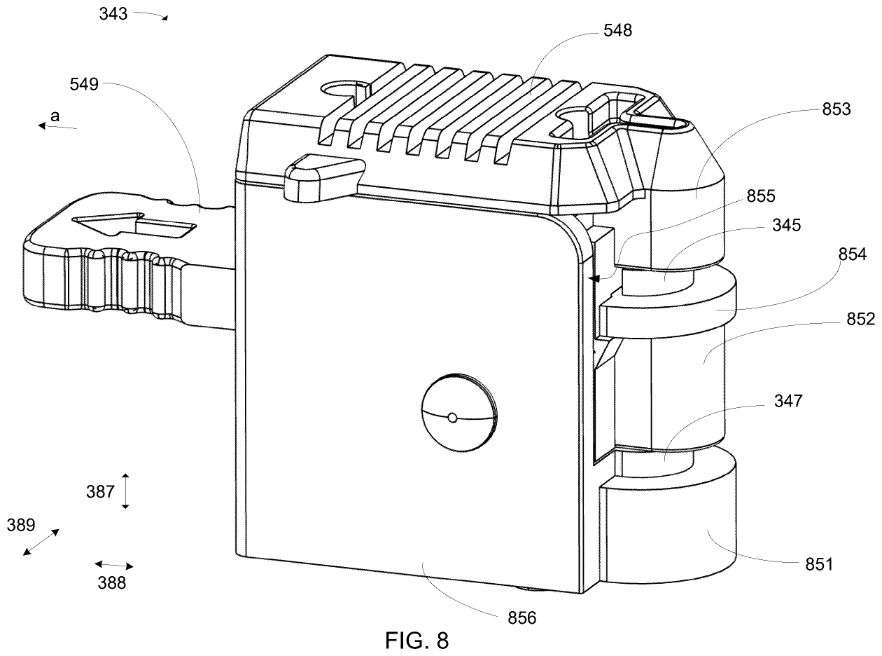

Now referring to FIG. 3-8 an example system 399 will be described. System 399 is an information processing system, such as a server, networking device, or other information processing system, and is one implementation example of system 299 described above. System 399 includes a primary system board 330 having an M.2 assembly 341 mounted thereon, an M.2 bay 332 defined in part by the M.2 assembly 341, and a device 300 removably installable in the M.2 bay 332. FIG. 3 shows the example system 399 in an uninstalled state of the device 300. FIG. 4 shows the system board 330 with the M.2 assembly 341 mounted thereon. FIG. 5 illustrates the system board 330 with M.2 SSDs 551 installed in the M.2 assembly 341. FIG. 6 shows system 399 with the device 300 partway in the process of being installed in M.2 assembly 341 (i.e., in a partially installed state). FIG. 7 illustrates system 399 with the device 300 in an installed state. FIG. 8 illustrates an example double stacked holder 343.

The device 300 and the system board 330 are described simultaneously below for ease of understanding. However, it should be noted that device 300 and the system board 300 may be produced or sold together or separately and may be claimed separately or together herein. The device 300 is an example implementation device 100 . The system board 330 with the M.2 assembly 341 mounted thereto is an example implementation of the system board 230 with the M.2 assembly 241. Elements in FIG. 3-8 and elements of FIGS. 1-2 whose reference numbers have the same last two digits as elements described above in relation to FIGS. 1 and 2, such as 102 and 302, correspond to one another, with elements in FIGS. 3-8 being one implementation example of the corresponding elements in FIGS. 1-2.

Elements in reference to FIGS. 3-8 are described using vertical 387, longitudinal 388 and latitudinal 389 directions for ease of description. Vertical direction 387 is perpendicular to a face of the primary system board 330 upon which the M.2 assembly 341 is mounted. Longitudinal 388 and latitudinal 389 directions are perpendicular to each other and to the vertical direction 387 and may both also be referred to as being a “horizontal” direction on occasion. However, it should be noted that these directional descriptions are used only relative to the position of the system board 330. As such, for example, vertical position 387 could include a horizontal position relative to the ground, depending on the orientation of the system board 330. Motions related to the installation of M.2 SSDs 551 and PCA 302 in reference to FIGS. 5 and 6 are described using alphabetical letters. For example, a first motion is described with the letters “a”, while a second motion is described with a letter “b”, and so forth.

The example PCA 302 comprises a PCB 301 with components 303 mounted thereto. The PCB 301 includes a first end with four M.2 edge connectors 312 and a second end with four attachment features 313. However, as mentioned above, other examples may include less or more than four M.2 edge connectors 312 and attachment features 313, depending on the use case of PCA 302.

The example M.2 edge connectors 312 includes pins configured to communicatively mate with M.2 sockets, such as M.2 sockets 342 described in further detail below. In instances, M.2 edge connectors 312 may be configured to mate with a M.2 M-key type of socket. In some instances, M.2 connector 312 may be configured to mate with a M.2 B-key type. In instances, M.2 connector 312 may be configured to mate a M.2 B+M-key type. In some examples, M.2 assembly 341 may be configured to receive pluggable modules having a M.2 22110 SSD form factor. This means that the M.2 sockets 342 and holders 343 are configured to be compatible with (to mate with) M.2 22110 SSD modules, and also that the spacing therebetween is appropriate to allow an M.2 22110 SSD module to fit therein while being connected to the socket 342 and held by the holder 343. The M.2 SSDs 551 described in reference to FIGS. 5-7 are of a M.2 22110 SSD form factor, in which case the device 300 would also have the length of a M.2 22110 SSD in order to fit into the M.2 assembly 341. Length is used herein to refer to the distance between a M.2 socket 342 and its respective holder 343. However, it should be noted that the device 300 may be manufactured and configured to fit into many other M.2 form factors M.2 assembly 341 not described in this disclosure.

The example attachment features 313 may include multiple forms. In this example, the attachment features 313 are shown as notches on PCB 301/PCA 302. However, it should be noted that the attachment features 131 may include other forms that are capable of attaching to a holder, such as an area protruding from the PCB 301/PCA 302. In some examples, attachment features 313 may be a separate component that itself attaches to the PCB 301/PCA 302 before being attached to the holders 343. For example, the attachment features 313 may be a clamp like bar that attaches to the PCB 301/PCA 302 and includes notches or protruding areas that attaches to the holders 343. As such, it should be noted that the notched configuration shown herein is provided only as an example, and many other types of attachments could be included in PCB 301/PCA 302.

The example component 303 may include any electrical or electro-optical component configured to be attached to the PCB 301 to form PCA 302. As mentioned above, component 303 is shown as a singular component for ease of description. Depending on the use case, component 303 would likely include a plurality of components. As mentioned above in reference to FIGS. 1 and 2, PCA 302 would likely include most or all electrical/electro-optical components that are utilized in the operation of the type of module PCA 302 is configured to operate as, with the exception of the attachment features and electrical connectors. For example, if device 300 is configured to operate as an OCP NIC. 3.0 module, PCA 302 may include components 303 of an OCP NIC. 3.0 module. As another example, if PCA 302 is configured to operate as a DC-SCM module, then PCA 302 may include most or all components of a DC-SCM.

In the example shown in FIGS. 3-8, M.2 assembly 341 has a stacked configuration that includes a lower connecting area and an upper connecting area. Pluggable modules (including device 300 and M.2 modules) can be installed in either or both of the lower connecting area and upper connecting area, and when modules are simultaneously installed in both the upper and lower connecting areas they may be vertically stacked relative to one another. In other examples, there may be more than two connecting areas to allow for modules to be installed in more than two vertically stacked tiers/layers. However, it should be noted that other examples may include other configurations such as a single-level configuration that would allow for installation of devices in a non-stacked manner.

The M.2 assembly 341 comprises M.2 sockets 342, which each comprise a standard M.2 socket. In other words, each M.2 socket 342 comprises a receptacle with pins arranged therein, wherein the shape/dimensions of the receptacle and the configuration of the pins complies with an M.2 standard/specification such that each M.2 socket 342 is capable of mating with a standard M.2 edge connector. The pins of each M.2 socket 342 are electrically connected to the system board 330. As mentioned previously, in this example the M.2 assembly 341 is in a stacked configuration, and therefore the example M.2 sockets 342 includes upper sockets 344 and lower sockets 346. The lower sockets 346 are used for connecting pluggable modules in a lower level of the stacked arrangement, while the upper sockets 344 are used for connecting pluggable modules in an upper level of the stacked arrangement. In the illustrated example, each upper socket 344 is stacked on top of a lower socket 346 forming a pair. Moreover, in this example, a pair of an upper socket 344 and a lower socket 346 may share the same housing (outer shell) in common—in other words, they are integrally connected together (two parts of the same unitary body). In other examples, the housings/shells of the upper and lower sockets could be physically distinct.

The pluggable modules which the sockets 342 are configured to receive may include M.2 modules (e.g., M.2 SSDs 551) and the device 300. These pluggable modules may be installed in the M.2 assembly 341 in a variety of arrangements. In FIGS. 5-7, one example arrangement is illustrated in which four M.2 SSDs 551 are installed in the lower level and connected to the lower sockets 346 while the device 300 is installed in the upper level and connected to the upper sockets 344. This is just one example arrangement, and in another arrangement M.2 SSDs 551 could be connected to the upper sockets 344 while the device 300 is connected to the lower sockets 346. In another arrangement, two of the devices 300 are installed, with one connected to lower sockets 342 and the other connected to the upper sockets 344 In some cases, device 300 is connected to the upper sockets 344 so there is enough space for component 303 (e.g., if device 300 is installed in the lower level, component 303 may interfere with modules installed in the upper level). In other cases device 300 may fit within the lower level without component 303 interfering with devices installed in the upper level. As mentioned throughout this disclosure, in some cases a second instance of device 300 may be installed in the lower sockets 346, depending on size of components installed or whether component spacers are used.

In examples, M.2 assembly 341 may include component spacers (not illustrated) placed between system board 330 and M.2 sockets 342/holder 343. In configurations where spacers are used, the lower socket 346 may also include the extra area in front of the socket for allowing M.2 connectors 312 to be placed on the socket before placing the opposite side on the holders 343. In examples where spacers are used, each socket 344/346 may receive a device or M.2 modules. It should be noted that depending on the size of the spacers, components 303 may fit both in the lower installation and the upper installation. The components spacers may be made of, or include, a plurality of materials such as plastic, aluminum, brass, ceramic, composite materials, and the like.

The example holders 343 includes an upper engagement section 345 and a lower engagement section 347. Referring to FIG. 5, example holder 343 also includes a movable section 548 and a movable feature 549. Movable section 548 is a section of the holder 343 that moves away from the area where the device 300 is placed as to allow the engagement features 313 to engage with upper engagement section 345. The movable feature 549 is another movable area of the holders 343 that are used to allow engagement with lower engagement section 347. In this example, movable feature 549 is a feature that is moved relative to the main body of the holder 343. In instances upper and lower engagement sections 345/347 may be a part of, or attached to, movable section and feature 548/549, respectively. For example, if movable section 548 is moved relative to the main body of holder 343, upper engagement section 345 would also be pulled away. In instances, movable section 548 and movable feature 549 are configured to be manually moved prior to insertion of device 300, or other components to be installed on M.2 assembly 341. In instances, movable section 548 may be a cap that can be removed from holder 343. In some instances, movable section 548 may be a movable piece that is moved outwards in the longitudinal 388 direction. In instances, movable feature 549 may be a movable piece that can be slid outwards from the holder 343. In instances, movable feature 549 may be a lever that can be pushed upwards or downwards, in the vertical 387 direction, as to move lower engagement section 347. An example holder 343, including the main body of the holder, will be described in more detail below in reference to FIG. 8.

Referring to FIG. 4, M.2 bay 332 comprises the volume of space positioned directly above the primary system board 330 and between the M.2 sockets 342 and M.2 holders 343, and also comprises the M.2 sockets 342 and M.2 holders 343. In FIGS. 4-7, only the section of the system board 330 adjacent the M.2 bay 332 is shown. It should be understood that the system board 330 may include additional components not illustrated, such as a processor, memory, etc.

Referring to FIG. 5, M.2 SSDs 551 are shown installed in M.2 assembly 341. In order to allow for one of the M.2 SSDs 551 to be installed in the M.2 assembly 341, both movable sections 548 and movable features 549 are moved outwards from the holders 343, in the longitudinal 388 direction. This moves the upper and lower engagement sections 345/347 out of the way to allow the attachment-side of each M.2 SSD 551 to be moved into its installation position on the base tip 851 (described below). The M.2 edge connector of the M.2 SSDs 551 may be inserted into a lower socket 346 before or simultaneously as the attachment side of the M.2 SSD 551 is moved into its installation position. Outwards in this figure is illustrated by arrow “a” showing longitudinal 388 movement. Once M.2 SSDs 551 are placed in the holder 343 and inserted into lower M.2 sockets 346, movable features 549 are moved back into their original position as to provide support for the M.2 SSDs 551 in the installed position.

A process of connecting PCA 301 to M.2 assembly 341 will now be described in reference to FIG. 6. As mentioned, FIG. 6 omits a depiction of the components 303 for illustrative purposes, but such components may nevertheless be present.

In this example, PCA 302 is shown being installed after the M.2 SSDs 551 are connected. It should be noted that this configuration is provided as an example only and other configurations may be included in other examples. For example, PCA 302 may be connected to the M.2 assembly 341 without the M.2 SSDs 551 being connected. In other examples, a second device similar to PCA 302 may be installed in the lower part of the stacked M.2 assembly 341. For other configurations, such as non-stacked M.2 sockets 342, the process would be substantially the same, with some possible variations such as the type of mechanism used for movable sections 548. For example, in a single engagement holder, movable section 548 could operate in, or have the same mechanism, of movable features 549.

In this example, referring to FIG. 6, M.2 edge connectors 312 of PCB 301 are first placed in engagement with the M.2 sockets 344, although in some cases without fully inserting the connectors 312 into the sockets 344. Two variations of the steps taken will be described. If the M.2 SSDs 551 are installed, according to FIG. 5, at the same time as device 300, then movable sections 548 may have already been moved in the direction shown by arrow “a.” If movable sections 548 are not currently in the outward position (e.g., because M.2 SSDs 551 are not installed or have been already installed at an earlier time), then movable sections 548 are moved in the direction “a” or removed from the holders 343, depending on the type of movable sections 548 used.

Once movable sections 548 are no longer blocking insertion of PCB 301, PCB 301 is pivoted such that attachment features 313 are moved downwards, in the vertical direction 387, shown by arrow “b.” Attachment features 313 are moved until they are placed on, or in contact with, upper engagement sections 345.

In some examples, the M.2 edge connectors 312 will have been fully seated within the sockets 344 prior to the PCB 301 being pivoted to move the attachment features 313 downward. For example, the M.2 edge connectors 312 are inserted into the sockets 344 while the device 300 is held at an angle relative to the system board 330. The angling of the device 300 allows for the M.2 edge connector 312 to engage the sockets 344 notwithstanding the other end of the PCB 301 sticking out beyond a front face 855 of the holder 343. The length of the PCB 301 may exceed the distance between the front face 855 of the holder 343 and the socket 344, which is labeled “w” in FIG. 4, and consequently it might not be possible to fit the device 300 between the sockets 344 and the holders 343 if the device 300 is parallel to the board 330. However, by tilting the device 300 at an angle, the edge connectors 312 can be inserted into the sockets 344 while the other end of the PCB 301 remains positioned above the holders 343, as shown in FIG. 6. Then, once the edge connectors 312 are inserted into the sockets 344, this moves the PCB laterally in the direction “c” sufficiently that the other end of the PCB 301 no longer sticks out beyond the front face 855 of the holders 343, and therefore the PCB 301 can now be pivoted downward without the PCB 301 colliding with the top of the holders 343.

In other examples, the M.2 edge connector 312 will have been only partially inserted into the M.2 sockets 344, or not inserted at all, prior to the PCB 301 being pivoted to move the attachment features 313 downward. In some of these examples, the M.2 sockets 344 are inserted the rest of the way into the M.2 sockets 344 simultaneously with the pivoting of the PCB 301. In others of these examples, the M.2 sockets 344 may be inserted the rest of the way into the M.2 sockets 344 after the pivoting of the PCB 301. In other words, in those examples, once the attachment features 313 are placed on upper engagement sections 345, then PCB 301 is moved in the longitudinal direction 388, shown by arrow “c,” until M.2 connectors 312 are fully inserted and in communicative connection with M.2 upper sockets 344, shown by dashed lines 681.

In some examples, movement of movable section 548 shown by arrow “a” may occur as an effect of movement shown by arrow “b” without the user manually moving the section 548. For example, as a user pushes attachment features 313 towards direction shown by arrow “b,” the movement causes the PCB 301 to collide with the upper movable tip 853 and the attachment features 313 to push movable section into direction “a.”Alternatively, a user may manually move the movable section 548. Once attachment feature 313 are in contact with the upper engagement sections 345, movable section 548 may be moved back to its original position.

In some examples, holder 343 includes a spring mechanism which biases the movable section 548 to its resting position shown in FIG. 8. Thus, in such examples, the motion of the movable section 548 in the direction “a” may be resisted by a spring force of the spring mechanism, such that sufficient force may need to be applied to overcome this spring force. Furthermore, in such examples, the returning of the movable section 548 to its original position may be caused, or assisted, by the spring force of the spring mechanism (e.g., a user may simply release the section 548 and allow the spring to return it to its original position). Furthermore, the spring mechanism may help to hold the section 548 in its original position, thus ensuring that device 300 remains secured to the holder 343, and preventing inadvertent release of the device 300 due to shock, vibration, etc. It should be noted that a similar spring mechanism may be attached to movable features 549 to bias them toward their original position in a similar manner, as it will be described in reference to FIG. 8.

Once PCB 301 is connected to M.2 assembly 341, through connection 681, movable sections 548 are moved back into its original position, thus forming attachment 682 between device 300 and holders 343. In some instances, movable sections 548 may be used to push PCB 301 towards M.2 sockets 344, because as upper engagement sections 345 are moved back towards the direction of the holders, the upper engagement sections 345 would naturally push the attachment features 313 towards the sockets as to keep device 300 in an attached position. It should be noted that this feature would depend on whether upper engagement sections 345 are a part of movable section 548. In instances, upper engagement sections may be attached to, or a part of, movable section 548 or movable feature 549. In some examples in which the device 300 is moved in the direction “c” after seating the attachment features 313 and in which a spring mechanism is included in the holder, the spring mechanism may cause or assist movement of device 300 in direction shown by arrow “c” due to the natural movement of the spring mechanism. In other words, the spring mechanism pushes (or helps to push) the device into an installed position once a user stops applying pressure against the spring mechanism.

FIG. 7 shows PCA 302 in an installed position. As noted above, for illustrative purposes components 303 were omitted from some of the figures. FIG. 7 shows PCA 302 installed with an example component 303. It should be noted that although only one component 303 is shown in this example, multiple components may be included with PCA 302. For example, PCA 302 may be used as a NIC 3.0, thus many of the components found in that form factor would be included in PCA 302.

FIG. 8 shows an example holder 343. The example holder 343 includes a main body 856, base tip 851, middle movable tip 852 and an upper movable tip 853. In this example, base tip 851 is part of the main body 856 of the holder 343. Base tip 851 may be attached to holder 343 or be a part of the holder 343, such as forming a monolithic structure. As described in reference to FIG. 5, an M.2 SSD 551 is placed on holder 343 and in contact with lower engagement section 347. To be in contact with lower engagement section 347, an engagement feature of M.2 SSD 551 would be placed on base tip 851. More specifically, lower engagement section 347 is configured to engage an M.2 attachment feature of a pluggable module (e.g., M.2 SSD 551, device 300, or some other module), wherein an M.2 attachment feature comprises a semi-circular notch or cutout in an edge of a PCB of the module, with location, shape, and dimensions as defined by the M.2 standards. Accordingly, in this example, the lower engagement section 347 has a semi-circular profile which is complementary to the semi-circular notch/cutout of the module so that the lower engagement section 347 can be inserted into the notch/cutout. In this example, engagement features of M.2 SSD 551 are similar to engagement features 313 of PCB 301. Although in other examples the engagement features may differ, in this example they are sufficiently similar at least in relation to the holder 343, as they would need to be shaped in a manner that enables attachment with the holder 343.

Continuing with the example holder 343 of FIG. 8, middle movable tip 852 is attached to, or a part of, movable feature 549. As described in reference to FIG. 5, movable feature 549 is moved outwards in the longitudinal direction 388 in order to enable insertion of a pluggable module (e.g., M.2 SSD 551). In this example, movement of movable feature 549 causes middle movable tip 852 to also be moved in the same direction. Once movable middle tip 852 is moved, one end of the pluggable module (M.2 SSD 552) can be placed on top of base tip 851 and in contact with lower engagement section 347. In this example, as it will be apparent based on FIG. 8, the pluggable module (e.g., an M.2 SSD 551) becomes attached to the holder 343 once middle movable tip 852 is moved back into its original position. Specifically, an edge of the pluggable module which has an attachment feature is sandwiched between the base tip 851 and the middle movable tip 852, which constrains vertical movement of the pluggable module, and simultaneously the lower engagement section 347 is engaged with (inserted into) the notch/cutout of the pluggable module which constrains horizontal motion of the pluggable module. Example holder also includes a top base 854 attached to, or a part of, middle movable tip 852 and used to hold attachment features 313. In some instances, upper engagement sections 345 may also be attached to, or part of, middle movable tip 852.

Continuing with reference to FIG. 8, upper movable tip 853 is attached to, or part of, movable section 548. As mentioned in reference to FIGS. 5 and 6, movable section 548 may be movable outwards or may be removed from holder 343. With either configuration, once upper movable tip 853 is moved, or removed, an edge of a pluggable module (e.g., device 300) may be placed on top base 854. Moreover, in this state, attachment feature of the pluggable module (e.g., attachment features 313) may be engaged with upper engagement feature 345. Upper engagement features 345, like lower engagement features 347, may be configured to engage M.2 attachment features, such as attachment features 313. When the movable section 548 is returned to its original position, an edge of a pluggable module may be sandwiched between upper movable tip 853 and top base 854, thus securing the pluggable module to the holder 343 in a manner similar to that already described above in relation to the lower engagement features 347.

In examples, engagement features 313 of device 300 may push against upper movable tip 853 to move movable section 548 in the direction shown by arrow “a.” As it is shown in the figure, upper movable tip 853 includes a reverse-funnel like top structure that aids in this process by guiding attachment features 313 towards upper engagement feature 345. In some examples, movable feature 549 may be attached to a spring mechanism. It should be noted that the spring mechanism is being described as an example, and that many other types of configurations could be included. For example, movable feature 549 may also include a separate spring mechanism.

In some instances, holder 343 may be a plastic holder. Although plastic provides the flexibility and structural resilience used in the use cases described herein, holder 343 may be made of, or include, materials not described herein. For example, holder may be made of metals coated with nonconductive sealant or rubber-like materials. It should be noted that holders 343 may be manufactured with any material capable of providing the attachment taught in this disclosure.

In the description above, various types of electronic circuitry are described. As used herein, “electronic” is intended to be understood broadly to include all types of circuitry utilizing electricity, including digital and analog circuitry, direct current (DC) and alternating current (AC) circuitry, and circuitry for converting electricity into another form of energy and circuitry for using electricity to perform other functions. In other words, as used herein there is no distinction between “electronic”circuitry and “electrical”circuitry.

It is to be understood that both the general description and the detailed description provide examples that are explanatory in nature and are intended to provide an understanding of the present disclosure without limiting the scope of the present disclosure. Various mechanical, compositional, structural, electronic, and operational changes may be made without departing from the scope of this description and the claims. In some instances, well-known circuits, structures, and techniques have not been shown or described in detail in order not to obscure the examples. Like numbers in two or more figures represent the same or similar elements.

In addition, the singular forms “a”, “an”, and “the” are intended to include the plural forms as well, unless the context indicates otherwise. Moreover, the terms “comprises”, “comprising”, “includes”, and the like specify the presence of stated features, steps, operations, elements, and/or components but do not preclude the presence or addition of one or more other features, steps, operations, elements, components, and/or groups. Components described as coupled may be electronically or mechanically directly coupled, or they may be indirectly coupled via one or more intermediate components, unless specifically noted otherwise. Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition.

And/or: Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}”.

Elements and their associated aspects that are described in detail with reference to one example may, whenever practical, be included in other examples in which they are not specifically shown or described. For example, if an element is described in detail with reference to one example and is not described with reference to a second example, the element may nevertheless be claimed as included in the second example.

Unless otherwise noted herein or implied by the context, when terms of approximation such as “substantially,” “approximately,” “about,” “around,” “roughly,” and the like, are used, this should be understood as meaning that mathematical exactitude is not required and that instead a range of variation is being referred to that includes but is not strictly limited to the stated value, property, or relationship. In particular, in addition to any ranges explicitly stated herein (if any), the range of variation implied by the usage of such a term of approximation includes at least any inconsequential variations and also those variations that are typical in the relevant art for the type of item in question due to manufacturing or other tolerances. In any case, the range of variation may include at least values that are within ±1% of the stated value, property, or relationship unless indicated otherwise.

Further modifications and alternative examples will be apparent to those of ordinary skill in the art in view of the disclosure herein. For example, the devices and methods may include additional components or steps that were omitted from the diagrams and description for clarity of operation. Accordingly, this description is to be construed as illustrative only and is for the purpose of teaching those skilled in the art the general manner of carrying out the present teachings. It is to be understood that the various examples shown and described herein are to be taken as exemplary. Elements and materials, and arrangements of those elements and materials, may be substituted for those illustrated and described herein, parts and processes may be reversed, and certain features of the present teachings may be utilized independently, all as would be apparent to one skilled in the art after having the benefit of the description herein. Changes may be made in the elements described herein without departing from the scope of the present teachings and following claims.

It is to be understood that the particular examples set forth herein are non-limiting, and modifications to structure, dimensions, materials, and methodologies may be made without departing from the scope of the present teachings.

Other examples in accordance with the present disclosure will be apparent to those skilled in the art from consideration of the specification and practice of the invention disclosed herein. It is intended that the specification and examples be considered as exemplary only, with the following claims being entitled to their fullest breadth, including equivalents, under the applicable law.

What is claimed is:

1. A device comprising:
a printed circuit board (PCB) configured to mate with an M.2 assembly of a primary board, the M.2 assembly comprising a plurality of M.2 sockets and at least one holder; and
one or more components mounted to the PCB;
wherein the PCB comprises:
a first end configured to mate with at least two M.2 sockets of the plurality of M.2 sockets of the M.2 assembly; and
a second end comprising at least one attachment feature and configured to removably engage with the at least one holder.

2. The device of claim 1, wherein the PCB has dimensions equivalent to a datacenter system controller module (DC-SCM) form factor.

3. The device of claim 2, wherein the first end of the PCB is configured to transmit DC-SCM signals through the at least two M.2 sockets to the primary system board.

4. The device of claim 3, wherein the PCB has all the functionalities of a DC-SCM except for DC-SCM connectors.

5. The device of claim 1, wherein the PCB has dimensions equivalent to an Open Compute Project (OCP) network interface card (NIC) 3.0 form factor.

6. The device of claim 5, wherein the first end of the PCB is configured to transmit OCP NIC 3.0 signals through the at least two M.2 sockets to the primary system board.

7. The device of claim 6, wherein the PCB has all the functionalities of a NIC 3.0 except for NIC 3.0 connectors.

8. The device of claim 1, wherein the M.2 assembly is configured to receive one or more M.2 modules having an M.2 22110 SSD form factor.

9. The device of claim 1, wherein the first end of the PCB is configured to mate with a B-key, a M-key or a B+M-key M.2 socket.

10. The device of claim 1, wherein the first end of the PCB comprises at least two M.2 edge connectors configured to mate, respectively, with the at least two M.2 sockets.

11. A computing system, comprising:
a chassis comprising a base;
a system board supported by the base, an M.2 bay comprising an M.2 assembly mounted to the system board, wherein the M.2 assembly comprises a plurality of M.2 sockets and one or more holders, wherein the M.2 bay is capable of receiving a plurality of M.2 pluggable modules installed concurrently therein;
a printed circuit assembly (PCA) configured to be installed in the M.2 bay, the PCA comprising a printed circuit board (PCB) and one or more components mounted to the PCB, the PCB comprising:
a first end configured to, in an installed state of the PCA in the M.2 bay, mate with at least two of the M.2 sockets of the M.2 assembly; and
a second end comprising at least one attachment feature and configured to, in the installed state of the PCA in the M.2 bay, removably engage with at least one holder of the one or more holders.

12. The system of claim 11, further comprising components spacers, wherein the component spacers are configured to elevate the M.2 sockets and the holders relative to the primary system board.

13. The system of claim 11, wherein the M.2 assembly has a double stacked configuration comprising a lower section and an upper section, and the PCA is configured to: mate with the upper section, mate with the lower section, or mate interchangeable with the upper section and the lower section.

14. The system of claim 13, wherein the M.2 assembly is configured to receive the plurality of M.2 pluggable modules and the PCA in at least a first arrangement; wherein in the first arrangement the plurality of M.2 pluggable modules are installed in the lower section and the PCA is installed in the upper section, stacked vertically above the plurality of M.2 modules.

15. The system of claim 14, wherein the M.2 assembly is configured to receive the PCA in a second arrangement in which the PCA is installed in the lower section and the plurality of pluggable M.2 modules or another PCA is installed in the upper section.

16. The system of claim 11, wherein the pluggable modules that the M.2 assembly is capable of concurrently receiving include M.2 modules having an M.2 22110 SSD form factor.

17. The system of claim 11, wherein the at least one holder is a plastic holder.

18. A method comprising:
placing a first side of a printed circuit board (PCB) in engagement with a plurality of M.2 sockets of an M.2 assembly ;
moving a second side, opposite of the first side, of the PCB towards an engagement section of a holder of the M.2 assembly, wherein the holder and the M.2 socket are attached to a primary system board;
causing a movable section of the holder to move sufficiently to allow the second side to be placed on the engagement section; and
inserting the first side of the PCB into the plurality of M.2 sockets until pins of the first side are electrically connected to respective socket pins of the plurality of M.2 sockets.

19. The method of claim 18, wherein the M.2 assembly has a stacked configuration comprising an upper section and a lower section, the upper section including the plurality of M.2 sockets and the holder, the lower section including a second plurality of M.2 sockets and a second holder, and wherein the PCB mates with the plurality of M.2 sockets and the holder located in the upper section.

20. The method of claim 19, further comprising, prior to installing the PCB in the upper section of the M.2 assembly, installing a M.2 pluggable module in a lower section of the M.2 assembly by engaging the M.2 pluggable module with an M.2 socket of the second plurality of M.2 sockets and with the second holder.
